(19) United States
(12) Patent Application Publication
(10) Pub. No.: US 2022/0367780 A1
(43) Pub. Date: Nov. 17, 2022

(54) SUPERCONDUCTING DEVICE

(71) Applicant: NEC Corporation, Tokyo (JP)

(72) Inventors: Kunihiko ISHIHARA, Tokyo (JP); Suguru Watanabe, Tokyo (JP); Katsumi Kikuchi, Tokyo (JP)

(73) Assignee: NEC Corporation, Tokyo (JP)

(21) Appl. No.: 17/741,659

(22) Filed: May 11, 2022

(30) Foreign Application Priority Data
May 17, 2021 (JP) 2021-082873

(51) Int. Cl. H01L 39/04

(52) U.S. Cl. CPC H01L 39/045

(57) ABSTRACT

A superconducting device according to an example embodiment includes: a superconducting chip; an interposer on which the superconducting chip is mounted; a socket that is arranged to face the interposer and includes a movable pin and a housing supporting the movable pin; and a board that is arranged to face the socket and includes a connector serving as an input/output with respect to the outside. In the board, one end of a terminal of a via hole is electrically connected to one end of a terminal of the movable pin, and a hole diameter of the via hole is smaller than a diameter of a tip portion of the movable pin connected to the via hole.

This application is based upon and claims the benefit of priority from Japanese Patent Application No. 2021-082873, filed on May 17, 2021, the disclosure of which is incorporated herein in its entirety by reference.

### TECHNICAL FIELD

The present disclosure relates to a superconducting device.

### BACKGROUND ART

Patent Literature 1 (WO 2018/212041) describes a quantum device (superconducting device) in which a superconducting chip utilizing a superconducting state is flip-chip mounted on an interposer. It is necessary to cool the superconducting device to a cryogenic temperature in order to use the superconducting device in the superconducting state.

When the superconducting chip is cooled to the cryogenic temperature, there is a possibility that a contact point with a terminal connected to the outside is disconnected due to stress and distortion caused by a volume change during cooling. In the above superconducting device, when one surface of the interposer is used for cooling by a sample stage, the number of the terminals connected to the outside is limited.

### SUMMARY

The present disclosure has been made to solve such a problem, and an object thereof is to provide a superconducting device capable of suppressing disconnection of a terminal connected to the outside and securing the terminal connected to the outside.

A superconducting device according to the present disclosure includes: a superconducting chip; an interposer on which the superconducting chip is mounted; a socket that is arranged to face the interposer and includes a movable pin and a housing supporting the movable pin; and a board that is arranged to face the socket and includes a connector serving as an input/output with respect to the outside. The board has a via hole formed therein, one end of a terminal of the via hole is electrically connected to one end of a terminal of the movable pin, and a hole diameter of the via hole is slightly smaller than a diameter of a tip portion of the movable pin connected to the via hole.

### BRIEF DESCRIPTION OF THE DRAWINGS

Exemplary features and advantages of the present invention will become apparent from the following detailed description when taken with the accompanying drawings in which:

FIG. 1 is a cross-sectional view illustrating a superconducting device according to a first example embodiment;

FIG. 2 is an exploded perspective view illustrating a superconducting chip and an interposer in the superconducting device according to the first example embodiment;

FIG. 3 is a cross-sectional view of an enlarged connection portion between a movable pin and a via hole in the superconducting device according to the first example embodiment;

FIG. 4 is a cross-sectional view illustrating modifications of the via hole of the first example embodiment;

FIG. 5 is a cross-sectional view illustrating a superconducting device according to a second example embodiment;

FIG. 6 is a cross-sectional view illustrating a superconducting device according to a modification of the second example embodiment;

FIG. 7 is a cross-sectional view illustrating a superconducting device according to a third example embodiment;

FIG. 8 is a cross-sectional view illustrating a superconducting device according to a modification of the third example embodiment; and

FIG. 9 is a cross-sectional view illustrating a superconducting device according to another modification of the third example embodiment.

### EXAMPLE EMBODIMENT

Quantum computing is a field in which data is manipulated using quantum mechanical phenomena (quantum bits). The quantum mechanical phenomenon refers to superposition of a plurality of states (different states with a plurality of quantum variables simultaneously occur), entanglement (a state in which a plurality of quantum variables is related regardless of space or time), and the like. The superconducting chip is provided with a quantum circuit that generates a quantum bit. The following description and drawings are given with omissions and simplifications as appropriate in order to clarify the description. In the drawings, the same elements are denoted by the same reference signs, and the redundant description thereof is omitted as necessary.

### First Example Embodiment

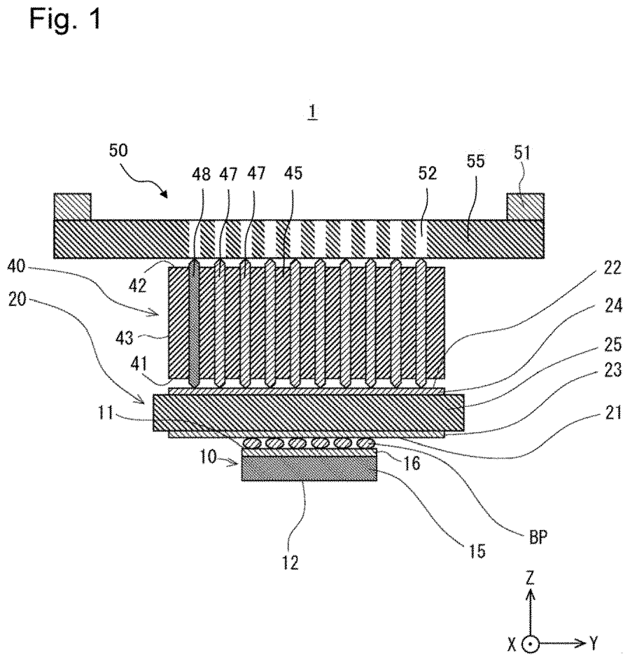

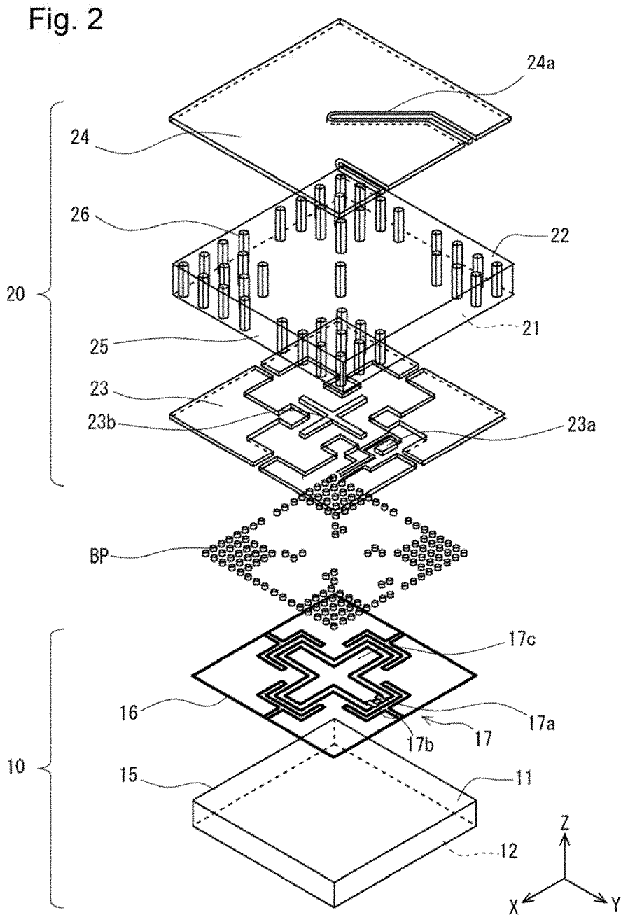

A superconducting device according to a first example embodiment will be described. FIG. 1 is a cross-sectional view illustrating the superconducting device according to the first example embodiment. FIG. 2 is an exploded perspective view illustrating a superconducting chip and an interposer in the superconducting device according to the first example embodiment. As illustrated in FIGS. 1 and 2, a superconducting device 1 includes a superconducting chip 10, an interposer 20, a socket 40, and a board 50.

The superconducting chip 10 includes a chip substrate 15 and a wiring layer 16. The chip substrate 15 contains, for example, silicon (Si). The chip substrate 15 is not limited to one containing silicon as long as the superconducting chip 10 can form the quantum bit, and may contain other electronic materials such as sapphire and compound semiconductor materials (Group IV, Group III-V, and Group II-VI). In addition, a single crystal is desirable, but a polycrystalline or amorphous crystal may be used.

A shape of the chip substrate 15 is, for example, a plate shape, and has one plate surface and another plate surface opposite to the one plate surface. One plate surface is referred to as a first surface 11, and the another plate surface is referred to as a second surface 12. Therefore, the superconducting chip 10 and the chip substrate 15 have the first surface 11 and the second surface 12. For example, the first surface 11 and the second surface 12 are rectangular. In the superconducting device 1, the first surface 11 faces the interposer 20 side. The first surface 11 is mounted on the interposer 20 using a bump BP.

The wiring layer 16 is provided on the first surface 11 side of the chip substrate 15. The wiring layer 16 contains, for example, a superconducting material such as niobium (Nb). The superconducting material used for the wiring layer 16 is not limited to niobium (Nb) and may be, for example, niobium nitride, aluminum (Al), indium (In), lead (Pb), tin (Sn), rhenium (Re), palladium (Pd), titanium (Ti), or an alloy containing at least one of these.

The wiring layer 16 includes a quantum circuit 17. In the quantum circuit 17, a resonator 17c having a loop circuit 17b in which superconducting materials are annularly connected by a Josephson junction 17a is formed. A material used for the Josephson junction is preferably Al, but may be another superconducting material. The quantum circuit 17 performs processing using the resonator 17c in a quantum state in superconduction. In this manner, the superconducting chip 10 includes the quantum circuit 17 and performs the processing using the quantum state.

The wiring layer 16 is mounted on the interposer 20 with the bump BP interposed therebetween. Accordingly, the superconducting chip 10 is flip-chip mounted on the interposer 20.

The bump BP may contain the superconducting material described above. The bump BP may contain the same superconducting material as the wiring layer 16 or may contain a different superconducting material from the wiring layer 16. When the bump BP includes a plurality of metal layers, at least one layer preferably contains a superconducting material. The bump BP may be formed in a layer including Nb (a wiring surface of the superconducting chip 10)/In (Sn, Pb, or an alloy containing at least any of these)/Ti/Nb (a wiring surface of the interposer 20)/Cu, a layer including Nb (a wiring surface of the superconducting chip 10)/Nb (a wiring surface of the interposer 20)/Cu, or a layer including Nb (a wiring surface of the superconducting chip 10)/In (Sn, Pb, or an alloy containing at least any of these)/Ta (a wiring surface of the interposer 20)/Cu. In the case of the bump BP containing Al and In, TiN may be used for a barrier layer in order to prevent alloying between Al and In. In this case, the bump BP may be formed in a layer including Al (a wiring surface of the superconducting chip 10)/Ti/TiN/In (Sn, Pb, or an alloy containing at least any of these)/TiN/Ti/Al (a wiring surface of the interposer 20)/Cu. Here, Ti is an adhesion layer. A preferred flip-chip connection is Nb (a wiring of the superconducting chip 10)/In/Ti/Nb (a wiring surface of the interposer 20)/Cu or Nb (a wiring of the superconducting chip 10)/Nb (a wiring surface of the interposer 20)/Cu. It is preferable to provide the bump with φ100 μm by adding the thickness of Cu in the range of 2 to 10 μm to the interposer wiring layer 23 having the thickness of 2 μm.

The interposer 20 includes interposer wiring layers 23 and 24, an interposer substrate 25, and through vias (hereinafter referred to as TVs 26). FIG. 1 does not illustrate the TV 26 to prevent the drawing from being complicated.

The interposer substrate 25 has, for example, a plate shape. The interposer substrate 25 contains, for example, silicon (Si). Note that the interposer substrate 25 is not limited to one containing silicon as long as the superconducting chip 10 can be mounted, and may contain other electronic materials such as sapphire, compound semiconductor materials (Group IV, Group III-V, and Group II-VI), glass, and ceramic. A surface of the interposer substrate 25 is preferably covered with a silicon oxide film (SiO₂, a TEOS film, or the like). The interposer substrate 25 and the interposer 20 have a mounting surface 21 on which the superconducting chip 10 is mounted and an opposing surface 22 opposite to the mounting surface 21.

Here, XYZ orthogonal coordinate axes are introduced for convenience of the description of the superconducting device 1. A plane parallel to the opposing surface 22 of the interposer 20 is defined as an XY plane, and a direction orthogonal to the opposing surface 22 is defined as a Z-axis direction. The +Z-axis direction is defined as the upper side, and the −Z-axis direction is defined as the lower side. Note that the upper side and the lower side are given for convenience of the description, and do not indicate directions in which the superconducting device 1 is actually arranged when being used.

For example, the superconducting chip 10 is arranged on the −Z-axis direction side of the interposer 20. The wiring layer 16 arranged on an +X-axis direction side of the superconducting chip 10 and the mounting surface 21 arranged on the −Z-axis direction side of the interposer 20 are connected through the bump BP.

The interposer wiring layer 23 is formed on the mounting surface 21 side of the interposer 20, that is, on the −Z-axis direction side of the interposer 20. The interposer wiring layer 23 contains the superconducting material described above. The interposer wiring layer 23 may contain the same superconducting material as the wiring layer 16, or may contain a different superconducting material from the wiring layer 16. For example, the interposer wiring layer 23 preferably contains Nb (0.1 μm in thickness), Cu (2 μm in thickness), and Ti in this order from the surface to the interposer substrate 25. For example, when the interposer substrate 25 contains silicon, the mounting surface 21 side of the interposer 20 preferably has a configuration of Nb/Cu/Ti/SiO₂/Si (the interposer substrate 25). The interposer wiring layer 23 is connected to the wiring layer 16 of the superconducting chip 10 through the bump BP.

The interposer wiring layer 23 may be a single layer or a multilayer. The interposer wiring layer 23 may include a magnetic field application circuit 23a and a reading unit 23b. The magnetic field application circuit 23a generates a magnetic field to be applied to the loop circuit 17b. As the magnetic field is applied to the loop circuit 17b, the quantum circuit 17 can function as a transmitter. The reading unit 23b reads information from the quantum circuit 17.

The interposer wiring layer 24 is formed on the opposing surface 22 side of the interposer substrate 25, that is, on the +Z-axis direction side of the interposer 20. The interposer wiring layer 24 may contain the superconducting material described above. The interposer wiring layer 24 may contain the same superconducting material as the wiring layer 16 and the interposer wiring layer 23, or may contain a different superconducting material from the wiring layer 16 and the interposer wiring layer 23. In addition, the interposer wiring layer 24 may contain a normal conducting material. The normal conducting material is, for example, copper (Cu), silver (Ag), gold (Au), platinum (Pt), or an alloy containing at least one of these. For example, the interposer wiring layer 24 preferably contains Cu and Ti in order from the surface to the interposer substrate 25. For example, when the interposer substrate 25 contains silicon, the opposing surface 22 side of the interposer 20 preferably has a configuration of Cu/Ti/SiO₂/Si (the interposer substrate 25).

The interposer wiring layer 24 may be a single layer or a multilayer. The interposer wiring layer 24 includes a terminal 24a configured to extract information from the superconducting chip 10 through the TV 26. Although only one terminal 24a is illustrated in FIG. 2, a plurality of the terminals 24a may be formed. In the superconducting device 1 of the present example embodiment, the opposing surface 22 can be utilized as much as possible for the terminal 24a configured to extract information.

The TV 26 penetrates the interposer substrate 25 from the mounting surface 21 side to the opposing surface 22 side. The interposer wiring layer 23 and the interposer wiring layer 24 are connected through the TV 26.

The TV 26 may contain the superconducting material described above. The TV 26 may contain the same superconducting material as the wiring layer 16 and the like, or may contain a different superconducting material from the wiring layer 16 and the like. In addition, the TV 26 may contain the normal conducting material described above. The TV 26 may contain the same normal conducting material as the interposer wiring layer 24, or may contain a different normal conducting material from the interposer wiring layer 24. For example, the TV 26 is formed by forming SiO₂ (for example, a thermal oxide film) on a sidewall of a through-hole with φ50 μm and filling the through-hole with Cu using Ti as the adhesion layer.

The socket 40 is arranged to face the interposer 20. For example, the socket 40 is arranged to face the opposing surface 22 of the interposer 20 in the present example embodiment. The socket 40 includes a housing 45 and a movable pin 47. In FIG. 1, some reference signs are omitted to prevent the drawing from being complicated.

The housing 45 has one end surface 41 and another end surface 42 opposite to the one end surface 41. In addition, the housing 45 has a side surface 43 that connects a peripheral edge of the one end surface 41 and a peripheral edge of the another end surface 42. The one end surface 41 faces the lower side toward the interposer 20, for example, and the another end surface 42 faces the upper side. The housing 45 holds the movable pin 47. The housing 45 may hold a plurality of the movable pins 47.

The housing 45 preferably contains an insulating material. At least a portion of the housing 45 in contact with the movable pin 47 contains the insulating material. The housing 45 preferably contains a non-magnetic material. Furthermore, the housing 45 preferably contains a material having a thermal expansion coefficient equivalent to a thermal expansion coefficient of the interposer 20.

The housing 45 may be made of a low-thermal-expansion composite material containing aluminum oxide (Al₂O₃, also called alumina), a mica-based machinable ceramic, aluminum nitride (AlN), zirconia (ZrO₂), a MACOR-based machinable ceramic, glass, a resin, a filler, and the like, or may contain a superconducting material as long as insulation from the movable pin 47 can be obtained.

The movable pin 47 is held by the housing 45. The movable pin 47 has one end and another end opposite to the one end. The movable pin 47 extends in the Z-axis direction, with the one end facing the lower side and the another end facing the upper side. Accordingly, the one end of the movable pin 47 protrudes from the one end surface 41 of the housing 45. The one end of the movable pin 47 is electrically in contact with, for example, the terminal 24a of the interposer 20. The another end of the movable pin 47 protrudes from the another end surface 42 and is electrically in contact with a terminal of the board 50. In this manner, the housing 45 has the one end surface 41 from which the one end of the movable pin 47 protrudes and the another end surface 42 from which the another end of the movable pin 47 protrudes. In FIG. 1, a space is formed between the one end surface 41 of the housing 45 and the interposer 20, but the space is not necessarily formed as long as the one end of the movable pin 47 can be in contact with the terminal 24a. Similarly, a space is formed between the another end surface 42 of the housing 45 and the board 50, but the space is not necessarily formed as long as the another end of the movable pin 47 can be in contact with a terminal of the board 50.

The one end and the another end of the movable pin 47 are connected in a conductive state with elastic means such as a coil spring and a plate spring interposed therebetween. The movable pin 47 may contain a superconducting material or a normal conducting material. The movable pin 47 may contain the same superconducting material as the wiring layer 16 and the like, or may contain a different superconducting material from the wiring layer 16 and the like. The movable pin 47 may contain the same normal conducting material as the interposer wiring layer 24, or may contain a different normal conducting material from the interposer wiring layer 24. The movable pin 47 is preferably a non-magnetic material. The movable pin 47 preferably contains, for example, a palladium alloy, a gold alloy, beryllium copper (BeCu), phosphor bronze, gold (plated with gold), niobium (Nb), niobium titanium (Nb—Ti), or titanium (Ti).

The socket 40 may have a positioning pin 48. The positioning pin 48 is a pin that determines an arrangement position of socket 40. The positioning pin 48 is held by the housing 45. The positioning pin 48 has, for example, one end protruding from the one end surface 41. The one end of the positioning pin 48 is connected to a predetermined position of the opposing surface 22 of the interposer 20 to determine the arrangement position of the socket 40. Note that a hole may be formed in the opposing surface 22 of the interposer 20, and the positioning pin 48 may be inserted into the hole to determine the arrangement position of the socket 40. As a result, positional displacement of socket 40 can be suppressed.

The board 50 is arranged to face the another end surface 42 of the socket 40. The board 50 includes a connector 51, a via hole 52, a board substrate 55, and the terminal. The board substrate 55 has, for example, a plate shape, and has an upper surface and a lower surface. The board substrate 55 may have a single layer structure or a multilayer structure. The lower surface of the board substrate 55 faces the socket 40. The terminal is provided on the lower surface of the board substrate 55. The connector 51 which serves as an input/output with respect to the outside is formed on the upper surface of the board substrate 55. The connector 51 of the board 50 is connected to the terminal of the board 50. The another end of the movable pin 47 is electrically in contact with the terminal of the board 50. A plurality of the terminals formed on the lower surface of the board 50 may be connected to each other. In this case, the terminal formed on the mounting surface 21 of the interposer 20 is connected to the connector 51 of the board 50 through the one end of the movable pin 47, the another end of the movable pin 47, the terminal formed on the lower surface of the board 50, and a terminal formed on the upper surface of the board 50 in this order. The terminal formed on the lower surface of the board 50 and the terminal formed on the upper surface (on the connector 51 side) of the board 50 are in electrical contact with each other.

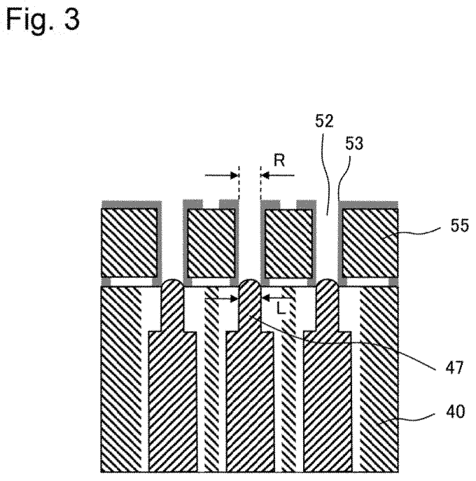

FIG. 3 is a cross-sectional view of an enlarged connection portion between the movable pin 47 and the via hole 52. As illustrated in FIG. 3, the via hole 52 is formed inside the board substrate 55. A plating layer 53 plated with copper or gold is formed on an inner wall of the via hole 52. The thickness of the plating layer 53 is, for example, 0.01 to 0.02 mm (10 to 20 um). In the present example embodiment, a hole diameter R of the via hole 52 indicates a portion obtained by removing the thickness of the plating layer 53 from the hole diameter of the via hole. As illustrated in FIG. 3, a tip portion of the movable pin 47 is in contact with an outer edge of the terminal of the via hole 52, and the terminal of the via hole 52 on the socket 40 side is electrically connected to the terminal on the another end side of the movable pin 47. The hole diameter R of the via hole 52 is slightly smaller than a diameter L of the tip portion of the another end of the movable pin 47, and is equal to or smaller than, for example, Φ0.1 mm. Specifically, the hole diameter R of the via hole 52 is smaller by 10 to 50% than the diameter L of the tip portion of the another end of the movable pin 47. As illustrated in FIG. 3, a through-hole of the housing 45 is slightly larger than the diameter of the movable pin 47, and there is a slight gap (between the socket 40 and the movable pin 47) around the movable pin 47.

The board 50 on which the connector 51 serving as the input from the outside and the output to the outside inputs and outputs power, a signal, and the like to and from the superconducting chip 10 through the socket 40 and the interposer 20.

Next, effects of the present example embodiment will be described. In the superconducting device 1 of the present example embodiment, the another end of the movable pin 47 is accommodated in a cavity of the via hole 52 since the hole diameter R of the via hole 52 formed in the board substrate 55 is slightly smaller than the diameter L of the tip portion of the another end of the movable pin 47. As a result, even if the movable pin 47 moves due to a volume change based on a difference b thermal expansion coefficient between the board substrate 55 and the socket 40 generated when the superconducting device 1 is cooled to a cryogenic temperature, the another end of the movable pin 47 can be kept in the state of being accommodated in the cavity of the via hole 52, and thus, the connection to the terminal of the via hole 52 can be maintained. Accordingly, disconnection can be more effectively prevented. When the hole diameter R of the via hole 52 is slightly smaller than the diameter L of the tip portion of the another end of the movable pin 47, the movable pin 47 does not fall into the via hole 52, and an electrically favorable connection state between the tip portion of the movable pin 47 and the terminal of the via hole 52 can be maintained. In addition, the through-hole of the housing 45 is slightly larger than the diameter of the movable pin 47, and the slight gap exists around the movable pin 47. As a result, the movable pin 47 fitted in the cavity of the via hole 52 can also cope with and follow a difference in thermal shrinkage.

Since the positioning pin 48 is provided, the arrangement position of the socket 40 can be easily determined. The positional displacement of the socket 40 can be suppressed by inserting the positioning pin 48 into the hole of the opposing surface 22.

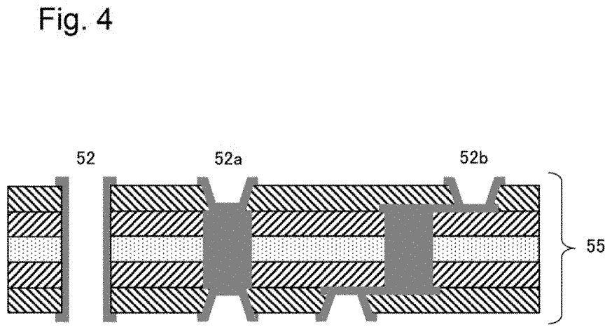

Next, modifications of the first example embodiment will be described. FIG. 4 is a cross-sectional view illustrating modifications of the via hole of the first example embodiment. As illustrated in FIG. 4, the board substrate 55 has a multilayer structure. A via hole of the present invention is not limited to the via hole described in the first example embodiment as long as another end of the movable pin 47 has a shape that fits into the cavity of the via hole 52. The plating layer 53 plated with copper or gold is formed on an inner wall surface of the via hole as in the via hole 52 in FIG. 4 in the via hole described in the first example embodiment. However, in a via hole 52a, the inside of the via hole is filled with copper or gold metal. In a via hole 52b, a plating layer extends in the horizontal direction between layers, and positions of the via hole are different between an upper surface and a lower surface of the board substrate 55. In addition, the inside of the via hole is filled with metal. Note that the modifications of the via hole illustrated in FIG. 4 illustrate examples of the via hole of the present invention, and the via hole of the present invention is not limited thereto. For example, as long as the surface of the board substrate 55 has a cavity or the like to be recessed, the inside thereof may be filled with metal or is not necessarily filled with metal.

### Second Example Embodiment

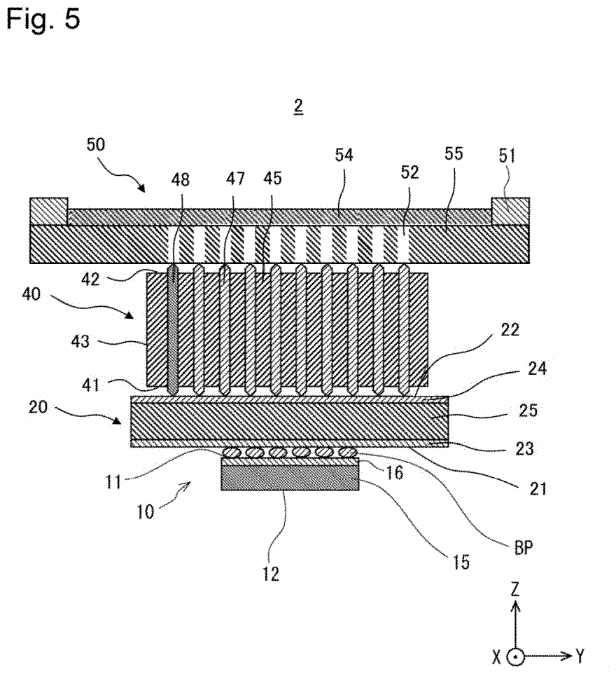

Next, a superconducting device according to a second example embodiment will be described. FIG. 5 is a cross-sectional view illustrating the superconducting device according to the second example embodiment. As illustrated in FIG. 5, a board wiring layer 54 electrically connected to the via hole 52 is provided on an upper surface (surface opposite to a surface facing the socket 40) of the board substrate 55.

The board 50 is arranged to face the another end surface 42 of the socket 40, which is similar to the above-described example embodiment. Then, the board wiring layer 54 electrically connected to the plating layer 53 of the via hole 52 is provided on the upper surface of the board substrate 55. The board wiring layer 54 is electrically connected to the connector 51. The board wiring layer 54 preferably contains a nonmagnetic material, and is, for example, copper and/or gold. In this case, a terminal formed on the mounting surface 21 of the interposer 20 is connected to the connector 51 through one end of a movable pin 47a, another end of the movable pin 47a, the plating layer 53 of the via hole 52, and the board wiring layer 54. Accordingly, the connector 51 inputs and outputs power, a signal, and the like to and from the superconducting chip 10 through the board 50, the socket 40, and the interposer 20.

Next, effects of the present example embodiment will be described. In a superconducting device 2 of the present example embodiment, the board wiring layer 54 electrically connected to the via hole 52 is provided on the upper surface of the board substrate 55. According to this configuration, the upper surface of the board substrate 55 is a space for wiring, impedance is easily matched. Accordingly, a transmission loss due to impedance mismatching can be suppressed as compared with a case where wiring is performed on a lower surface (on the socket 40 side) of the board substrate 55. Since the board wiring layer 54 is provided on the upper surface of the board substrate 55, it is possible to increase a contact area between a sample stage 30 to be described later and the lower surface of the board 50.

(Modification)

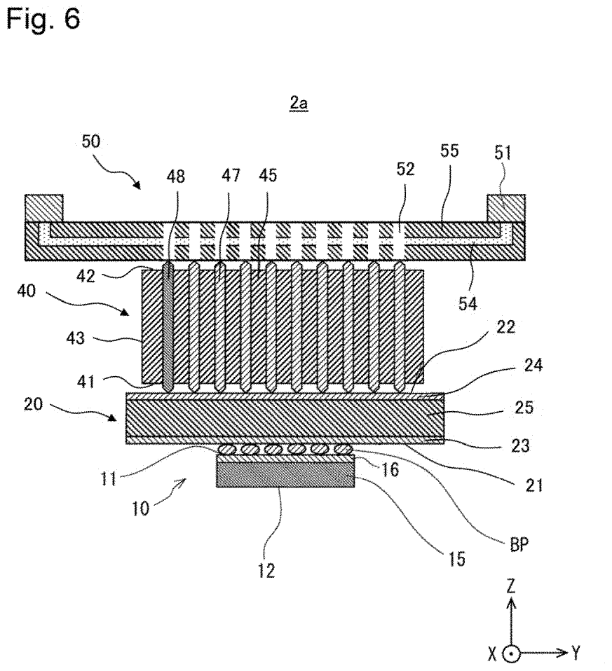

Next, a modification of the superconducting device according to the second example embodiment will be described. In a superconducting device 2a according to the modification of the second example embodiment, the board substrate 55 has a multilayer structure including a plurality of insulating layers and a plurality of conductor layers, and a wiring layer is formed inside the board substrate 55. Specifically, the board wiring layer 54 is formed on at least a part of the plurality of conductor layers excluding a surface of the board substrate 55 facing the movable pin 47. For example, as illustrated in FIG. 6, the board wiring layer 54 is provided inside the board substrate 55. The board wiring layer 54 is arranged between layers in the board substrate 55 having the multilayer structure, and extends in a direction (the Y-axis direction) orthogonal to a direction (the Z-axis direction) in which the via hole 52 extends. Both ends of the board wiring layer 54 are connected to the connector 51 of the board 50. In this case, a terminal formed on the mounting surface 21 of the interposer 20 is connected to the connector 51 of the board 50 through one end of the movable pin 47, another end of the movable pin 47, a terminal formed on a lower surface of the board 50, and the board wiring layer 54 in this order.

The superconducting device 2a includes the board wiring layer 54 inside the board substrate 55. As a result, wiring can be designed only with the board substrate 55 regardless of an installation state of the socket 40, and impedance matching can be more easily achieved.

### Third Example Embodiment

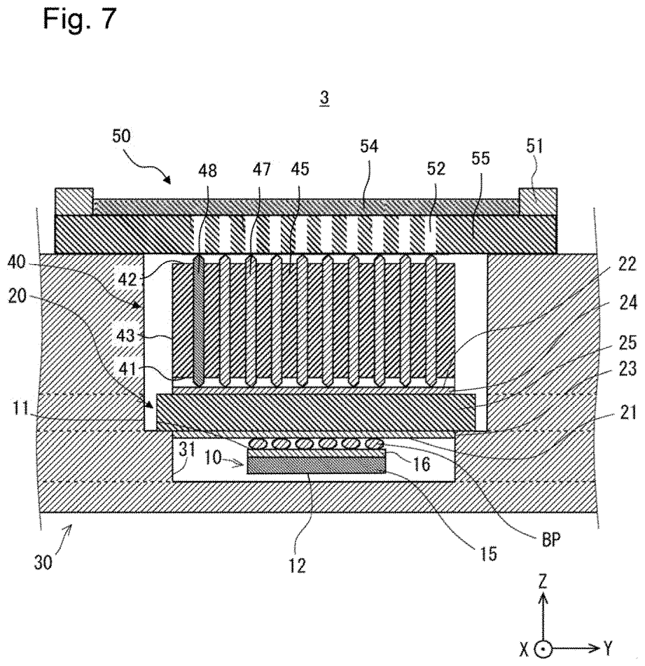

Next, a superconducting device according to a third example embodiment will be described. FIG. 7 is a cross-sectional view of a modification of the superconducting device according to the third example embodiment. As illustrated in FIG. 7, at least a part of the interposer 20 and at least a part of the board 50 according to the third example embodiment are in contact with the sample stage 30 having a cooling function. In a superconducting device 3, the side surface 43 of the housing 45 is arranged with a space interposed between the side surface and the sample stage 30 having the cooling function.

The sample stage 30 has the cooling function. For example, the sample stage 30 is a cold stage that can be cooled to a cryogenic temperature of about 10 [mK] by a refrigerator. The sample stage 30 preferably contains, for example, metal such as Cu, a Cu alloy, and Al. In the case of the sample stage 30 containing Al, insulation by alumite treatment may be performed. The superconducting device 3 of the present example embodiment uses, for example, a superconducting phenomenon at a cryogenic temperature equal to or lower than 9.2 [K] in the case of containing Nb or equal to or lower than 1.2 [K] in the case of containing Al as a superconducting material of the superconducting chip 10. Thus, the sample stage 30 that can be cooled to such a cryogenic temperature is used.

A recess 31 is formed in the sample stage 30. The superconducting chip 10 is smaller than the recess 31 when viewed from above through the interposer 20. On the other hand, the interposer 20 is larger than the recess 31 when viewed from above. The superconducting chip 10 is arranged inside the recess 31 formed in the sample stage 30 having the cooling function, and the second surface 12 of the superconducting chip 10 is not in contact with the sample stage 30. A part of the mounting surface 21 of the interposer 20 on which the superconducting chip 10 is mounted is in contact with an upper surface of the sample stage 30, and the opposing surface 22 of the interposer 20 is not in contact with the sample stage 30.

The interposer wiring layer 23 is not necessarily formed in a portion of the mounting surface 21 of the interposer 20 being in contact with the sample stage 30. In addition, the interposer wiring layer 23 may be formed as long as an insulating film is formed in the portion of the mounting surface 21 in contact with the sample stage 30 in order to prevent electrical conduction with the sample stage 30. It is preferable to bring the periphery of the superconducting chip 10 into a vacuum state or a reduced pressure atmosphere in order to improve a heat insulating property to reduce a temperature change in the periphery of the superconducting chip.

Next, effects of the present example embodiment will be described. In the superconducting device 3 of the present example embodiment, at least a part of the interposer 20 and at least a part of the board 50 are in contact with the sample stage 30. As a result, the interposer 20 and the board 50 are used as heat flow paths, and thus, the quantum circuit 17 in the superconducting chip 10 can be cooled to a cryogenic temperature, and the superconducting phenomenon can be utilized.

Since the opposing surface 22 of the interposer 20 is not in contact with the sample stage 30, the opposing surface 22 of the interposer 20 can be used as much as possible for the terminal 24a configured to extract information from the superconducting chip 10. Accordingly, the number of the terminals for extraction of information can be increased.

The superconducting chip 10 is arranged inside the sample stage 30 having the cooling function and is not in contact with the sample stage 30. That is, the second surface 12 of the superconducting chip 10 is arranged with a space interposed between the second surface and an inner surface of the recess 31 of the sample stage 30. With such a configuration, it is possible to suppress stress and distortion due to a shrinkage difference between the superconducting chip 10 and the sample stage 30 caused by a temperature change to a cryogenic temperature. The other configurations and effects are included in the description of the first and second example embodiments.

(First Modification)

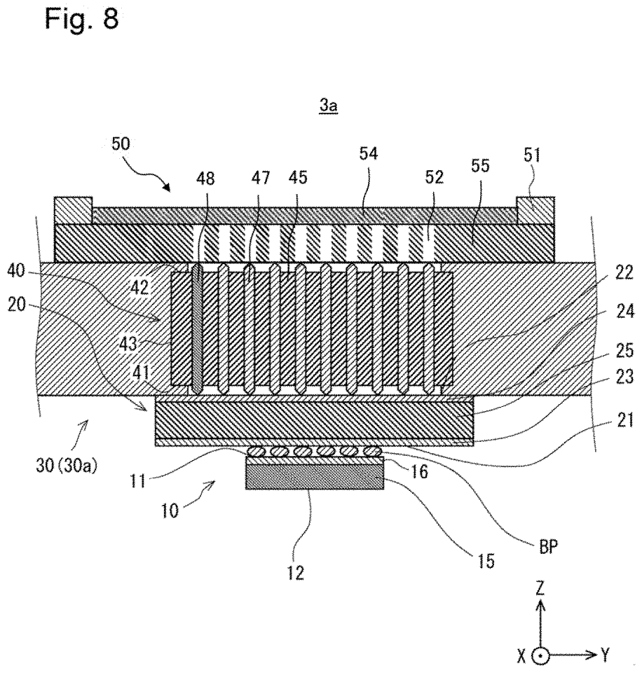

Next, a modification of the superconducting device according to the third example embodiment will be described. FIG. 8 is a cross-sectional view of a superconducting device according to the modification of the third example embodiment. As illustrated in FIG. 8, a part of a lower surface of the board 50 is in contact with the sample stage 30 having a cooling function in a superconducting device 3a. In the superconducting device 3a, the side surface 43 of the housing 45 is in contact with the sample stage 30 having the cooling function. The sample stage 30 includes, for example, plate-like portions 30a. The plate-like portions 30a sandwich the side surface 43 of the housing 45. In the superconducting device 3a, not only the side surface 43 of the housing 45 but also a part of the one end surface 41 of the housing 45 may be in contact with the sample stage 30 or a part of the another end surface 42 of the housing 45 may be in contact with the sample stage 30.

In the superconducting device 3a of the present example embodiment, at least a part of a lower surface of the board 50 and the side surface 43 of the housing 45 are in contact with the sample stage 30. As a result, the board 50 is used as a heat flow path, and thus, the quantum circuit 17 in the superconducting chip 10 can be cooled to a cryogenic temperature, and a superconducting phenomenon can be utilized.

(Second Modification)

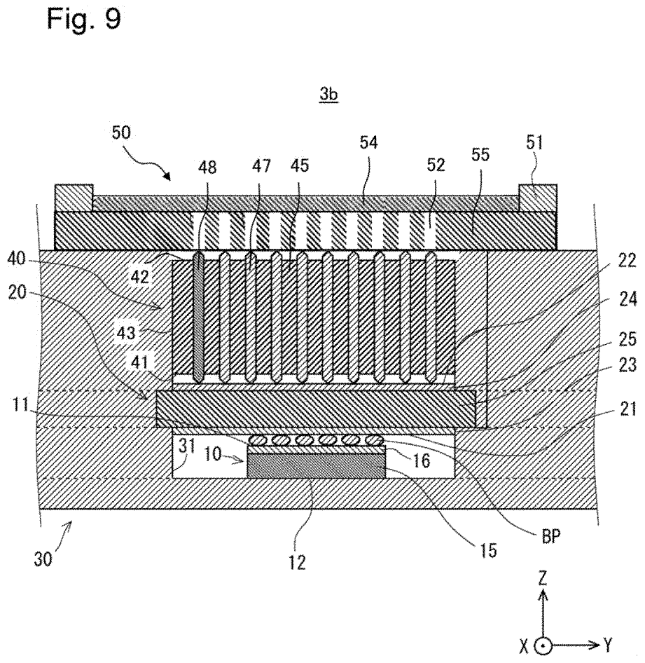

Next, another modification of the superconducting device according to the third example embodiment will be described. In a superconducting device 3b according to the another modification of the third example embodiment, at least a part of the superconducting chip 10, at least a part of the interposer 20, at least a part of the socket 40, and at least a part of the board 50 are in contact with the sample stage 30 having a cooling function. FIG. 9 is a cross-sectional view of the superconducting device according to the another modification of the third example embodiment.

As illustrated in FIG. 9, in the superconducting device 3b, at least a part of the superconducting chip 10, at least a part of the interposer 20, at least a part of the socket 40, and at least a part of the board 50 are in contact with the sample stage 30. Specifically, for example, the superconducting chip 10, the interposer 20, and the socket 40 are arranged inside the recess 31 of the sample stage 30. The second surface 12 of the superconducting chip 10, a side surface of the interposer 20, and the side surface 43 of the socket 40 are in contact with an inner surface of the recess 31 of the sample stage 30, and a lower surface of the board 50 is in contact with the plate-like portions 30a of the sample stage 30. Further, either the mounting surface 21 and the opposing surface 22 of the interposer 20 or the one end surface 41 and the another end surface 42 of the socket 40 may be partially in contact with the sample stage 30.

The superconducting chip 10 is smaller than the recess 31 when viewed from above through the interposer 20. On the other hand, the interposer 20 is larger than the recess 31 when viewed from above. The superconducting chip 10 is arranged inside the recess 31 formed in the sample stage 30 having the cooling function. Meanwhile, a part of the mounting surface 21 of the interposer 20 on which the superconducting chip 10 is mounted is in contact with an upper surface of the sample stage 30.

In the superconducting device 3b, the superconducting chip 10, the interposer 20, the socket 40, and the board 50 are partially in contact with the sample stage 30, and thus, cooling performance of the superconducting device 3 can be improved.

The superconducting chip 10 is arranged inside the sample stage 30 having the cooling function. The second surface 12 of the superconducting chip 10 is in contact with the inner surface of the recess 31 of the sample stage 30. At least a part of the second surface 12 may be in contact with the inner surface of the recess 31. With such a configuration, the superconducting chip 10 can be cooled by heat conduction of the sample stage 30 from the second surface 12 side, and the cooling performance can be improved. Accordingly, the quantum circuit 17 in the superconducting chip 10 can be stably operated.

Although the invention of the present application has been described above with reference to the example embodiments, the invention of the present application is not limited to the above example embodiments, and can be appropriately modified within a scope not departing from the gist. For example, a configuration in which a plurality of the superconducting chips 10 are connected to the interposer 20 and a configuration in which a plurality of the interposers 20 are connected to the socket 40 are also included in the scope of the technical idea of the present example embodiments.

According to the present disclosure, it is possible to provide the superconducting device capable of suppressing the disconnection of the terminal connected to the outside and securing the terminal connected to the outside.

While the invention has been particularly shown and described with reference to example embodiments thereof, the invention is not limited to these embodiments. It will be understood by those of ordinary skill in the art that various changes in form and details may be made therein without departing from the spirit and scope of the present invention as defined by the claims.

1. A superconducting device comprising:
a superconducting chip;
an interposer on which the superconducting chip is mounted;
a socket that is arranged to face the interposer and includes a movable pin and a housing supporting the movable pin; and
a board that is arranged to face the socket and includes a connector serving as an input/output with respect to an outside,
wherein a via hole is formed in the board, one end of a terminal of the via hole is electrically connected to one end of a terminal of the movable pin, and a hole diameter of the via hole is smaller than a diameter of a tip portion of the movable pin connected to the via hole.

2. The superconducting device according to claim 1, wherein
the board includes a wiring layer connected to the via hole, and the wiring layer and the connector are electrically connected.

3. The superconducting device according to claim 2, wherein
the wiring layer is arranged on a surface opposite to a surface facing the socket.

4. The superconducting device according to claim 2, wherein
the board has a multilayer structure including a plurality of insulating layers and a plurality of conductor layers, and the wiring layer is formed inside the board.

5. The superconducting device according to claim 1, wherein
a part of at least one of the superconducting chip, the interposer, the socket, and the board is in contact with a sample stage having a cooling function.

6. The superconducting device according to claim 5, wherein
the superconducting chip is arranged inside a recess formed in the sample stage having the cooling function, and
a part of the interposer is in contact with the sample stage.

7. The superconducting device according to claim 6, wherein
the superconducting chip has a first surface mounted on the interposer and a second surface opposite to the first surface, and
at least a part of the second surface is in contact with an inner surface of the recess.

8. The superconducting device according to claim 1, wherein
the housing has one end surface from which one end of the movable pin protrudes, another end surface from which another end of the movable pin protrudes, and a side surface connecting a peripheral edge of the one end surface and a peripheral edge of the another end surface, and
a part of at least one of the one end surface, the another end surface, and the side surface is in contact with a sample stage having a cooling function.
